(19) United States
(12) Patent Application Publication
(10) Pub. No.: US 2016/0007502 A1
(43) Pub. Date: Jan. 7, 2016

(54) HEAT EXCHANGER, COOLING SYSTEM, AND ELECTRONIC DEVICE

(71) Applicant: FUJITSU LIMITED, Kawasaki-shi (JP)

(72) Inventors: Nobuyuki HAYASHI, Yokohama (JP); TERU NAKANISHI, Isehara (JP); Yasuhiro Yoneda, Machida (JP)

(21) Appl. No.: 14/857,881

(22) Filed: Sep. 18, 2015

Related U.S. Application Data
(63) Continuation of application No. PCT/JP2013/058391, filed on Mar. 22, 2013.

(51) Int. Cl. H05K 7/20

(52) U.S. Cl. CPC H05K 7/20254

(57) ABSTRACT

An object of technology disclosed herein is improving cooling efficiency.

A heat exchanger includes plural pipes and a tank. The plural pipes are arrayed side-by-side. The tank couples together end portions of neighboring pipes among the plurality of pipes, and allows a coolant to flow from one of the neighboring pipes to another of the neighboring pipes.

### CROSS-REFERENCE TO RELATED APPLICATION

This application is a continuation application of International Application No. PCT/JP2013/058391, filed on Mar. 22, 2013, the disclosure of which is incorporated herein by reference in its entirety.

### FIELD

Technology disclosed herein relates to a heat exchanger, a cooling system, and an electronic device.

### BACKGROUND

Condensers have hitherto been known that are provided with plural pipes arrayed side-by-side, and an aggregator provided by the side of the plural pipes. In such condensers, a coolant flows through several pipes simultaneously and in parallel, and the flow of the coolant flowing in the pipes converges in a single aggregator. Moreover, coolant that has converged in the aggregator is conveyed outside through several other pipes.

### Related Patent Documents

Japanese Laid-Open Patent Publication No. 2006-214714

However, in such condensers, bubbles are generated in the plural pipes provided in front of the aggregator due to temperature increase, agitation, and the like in the coolant, and the bubbles remain in the pipes in some cases. In such cases, there is a concern that the flow velocity of the coolant may decrease, and heat transfer by the coolant may decrease, thereby decreasing cooling efficiency.

According to an aspect of the embodiments, a heat exchanger includes a plurality of pipes arrayed side-by-side; and a tank that couples together end portions of neighboring pipes among the plurality of pipes, and that allows coolant to flow from one of the neighboring pipes to another of the neighboring pipes.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view of an electronic device of an exemplary embodiment.

FIG. 2 is a side face view of an electronic device.

FIG. 3 is a front face view of a condenser.

FIG. 4 is a plan view of a condenser.

FIG. 5 is a cross-section plan view of relevant components of a condenser.

FIG. 6 is a cross-section plan view of relevant components of a condenser.

FIG. 7 is a cross-section front face view of a condenser.

FIG. 8 is a cross-section front face view of relevant components of a condenser.

FIG. 9 is a cross-section front face view of relevant components of a condenser.

FIG. 10 is a cross-section side face view of a condenser.

FIG. 11 is a cross-section side face view of a condenser.

FIG. 12 is a cross-section plan view of relevant components of a condenser.

FIG. 13 is a cross-section plan view of relevant components of a condenser.

FIG. 14 is a graph illustrating a comparison between measurement results for an exemplary embodiment and a comparative example.

FIG. 15 is a cross-section front face view illustrating a modified example of a tank.

FIG. 16 is a cross-section front face view illustrating a modified example of a tank.

FIG. 17 is a cross-section front face view illustrating a modified example of a tank.

FIG. 18 is a plan view illustrating a modified example of a flow regulating member.

FIG. 19 is a plan view illustrating a modified example of a flow regulating member.

FIG. 20 is a plan view illustrating a modified example of a flow regulating member.

FIG. 21 is a plan view illustrating a modified example of a flow regulating member.

FIG. 22 is a plan view illustrating a modified example of a condenser.

FIG. 23 is a plan view illustrating a modified example of a condenser.

FIG. 24 is a front face view illustrating a modified example of a condenser.

FIG. 25 is a front face view illustrating a modified example of a condenser.

### DESCRIPTION OF EMBODIMENTS

Explanation follows regarding an exemplary embodiment of technology disclosed herein.

An object of an aspect of technology disclosed herein is to improve cooling efficiency.

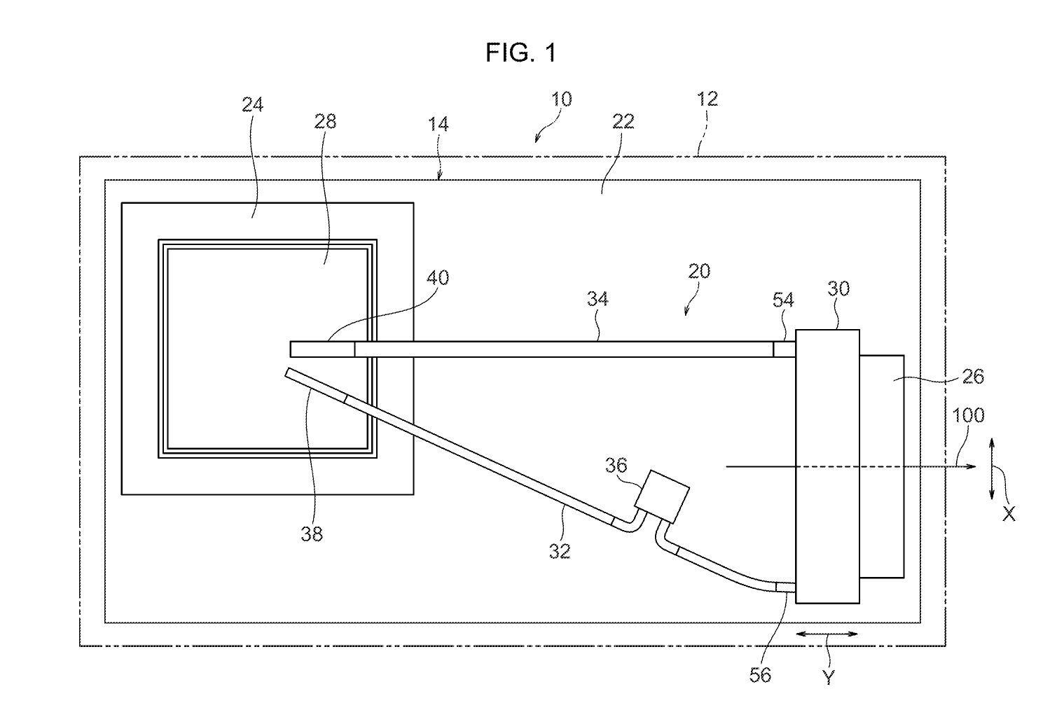

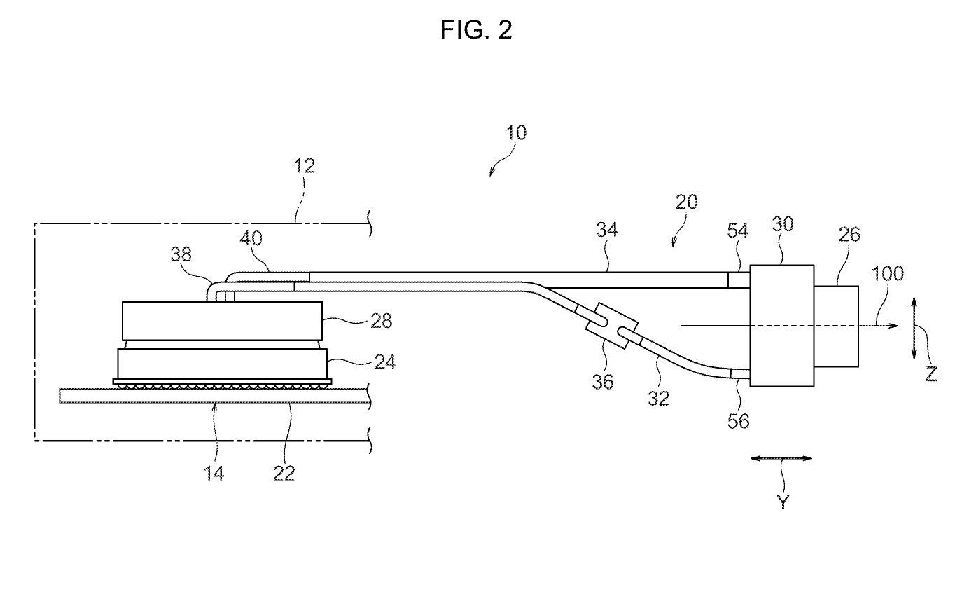

As illustrated in FIG. 1 and FIG. 2, an electronic device 10 includes a rack 12, a circuit unit 14, and a cooling system 20. The circuit unit 14 and the cooling system 20 are housed in the flattened box-type rack 12.

The circuit unit 14 includes a substrate 22 that is rectangular in plan view. A heat generating body 24 is mounted on the substrate 22. The heat generating body 24 is a heat generating component such as a central processing unit (CPU) or a power source module.

The cooling system 20 includes a fan 26, an evaporator 28, a condenser 30, a dispatch pipe 32, a return pipe 34, and a circulation pump 36. The fan 26 is provided on the substrate 22. Cooling airflow 100 is supplied to the heat generating body 24, the evaporator 28, and the condenser 30 when the fan 26 is driven.

The evaporator 28 is an example of a heat-receiver in which a coolant absorbs heat generated by the heat generating body. The evaporator 28 is fixed onto the heat generating body 24, and is in thermal contact with the heat generating body 24. The interior of the evaporator 28 is provided with a space into which the condensed coolant is supplied. The heat generated by the heat generating body 24 vaporizes the coolant in the evaporator 28 when the liquefied coolant (the hydraulic fluid in the liquid phase) is supplied to the evaporator 28.

The condenser 30 is formed substantially in a rectangular block shape, and the length direction thereof is disposed along a direction orthogonal to the direction of the flow of the cooling airflow 100 generated by the fan 26 in plan view. The condenser 30 is provided adjacent to the fan 26, and is disposed between the heat generating body 24 and the fan 26. The coolant is condensed due to exchanging heat with the cooling airflow 100 in the condenser 30 when the vaporized coolant (the hydraulic fluid in the gas phase) is supplied to the condenser 30. The condenser 30 is an example of a heat dissipater (heat exchanger) that dissipates heat from a coolant by exchanging heat with an external fluid. The cooling airflow 100 is an example of an external fluid. Detailed description of a specific structure of the condenser 30 is given below.

A top wall portion of the evaporator 28 described above is provided with an inlet 38, and the inlet 38 is coupled to an outlet 56 of the condenser 30, described below, by the dispatch pipe 32. The top wall portion of the evaporator 28 is provided with an outlet 40 adjacent to the inlet 38, and the outlet 40 is coupled to an inlet 54 of the condenser 30, described below, by the return pipe 34. Moreover, the circulation pump 36 is provided to the dispatch pipe 32.

When the circulation pump 36 is driven, the coolant is circulated between the evaporator 28 and the condenser 30, via the dispatch pipe 32 and the return pipe 34. Heat generated by the heat generating body 24 vaporizes the coolant in the evaporator 28, and the coolant is condensed in the condenser 30 due to exchanging heat with the cooling airflow 100. The heat of the evaporator 28 is conveyed to the condenser 30 through the coolant, and the heat generating body 24 is cooled, by repeatedly performing evaporation in the evaporator 28 and condensation in the condenser 30.

Detailed explanation next follows regarding a specific structure of the condenser 30 described above.

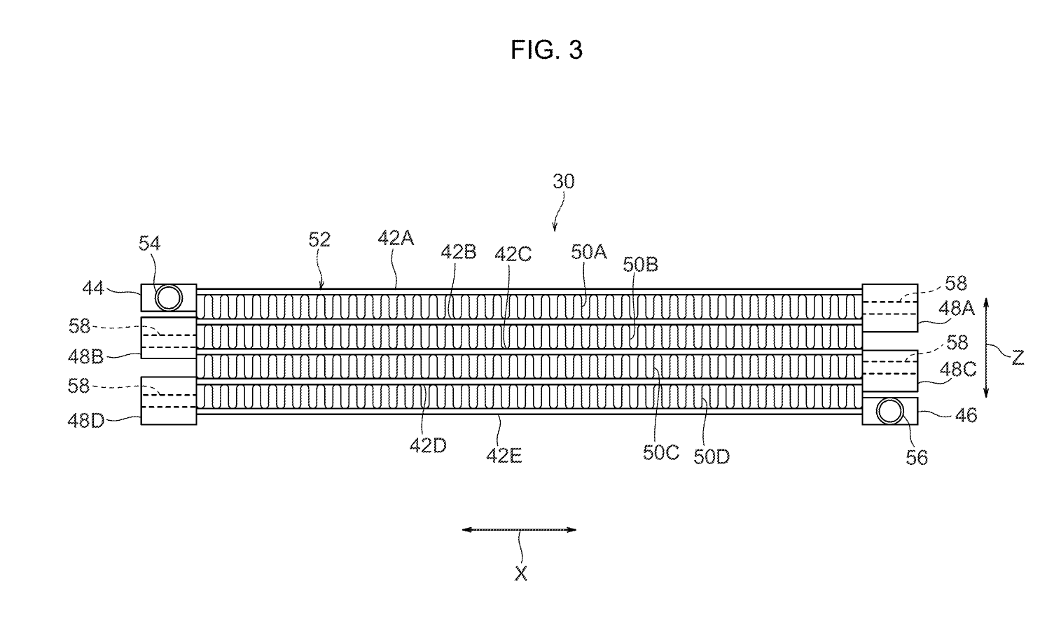

As illustrated in FIG. 3, the condenser 30 includes plural pipes 42A to 42E, an inlet side coupling member 44, an outlet side coupling member 46, and plural tanks 48A to 48D that are examples of a coupling portion.

The plural pipes 42A to 42E each extend along a horizontal direction of the condenser 30 (an x-direction that is a lateral direction), and are arrayed side-by-side and separated from each other at intervals along a vertical direction of the condenser 30 (a z-direction that is a height direction). Each of the pipes 42A to 42E has a flattened shape, and each of the pipes 42A to 42E is disposed with its thickness direction along the vertical direction of the condenser 30.

Respective heat dissipation fins 50A to 50D are interposed between neighboring pipes among the plural pipes 42A to 42E. As an example, the heat dissipation fins 50A to 50D employ a thin plate that is made from a metal with high thermal conductivity and that is bent into a corrugated shape.

The pipe 42A disposed at the uppermost level out of the plural pipes 42A to 42E is the pipe that is furthest to the upstream side and that is connected to the inlet side coupling member 44, described below. No heat dissipation fin is provided above the pipe 42A, which is furthest to the upstream side. The pipe 42A, which is furthest to the upstream side, is exposed at the opposite side from the side of the heat dissipation fin 50A interposed between the pipe 42A and the pipe 42B, which is the pipe on the second level from the upstream side, and the pipe 42A forms an upper end of the condenser 30. The pipe 42E, which is disposed at the lowermost level, is a pipe that is furthest to the downstream side and that is connected to the outlet side coupling member 46, described below. The pipe 42E, which is furthest to the downstream side, forms a lower end of the condenser 30.

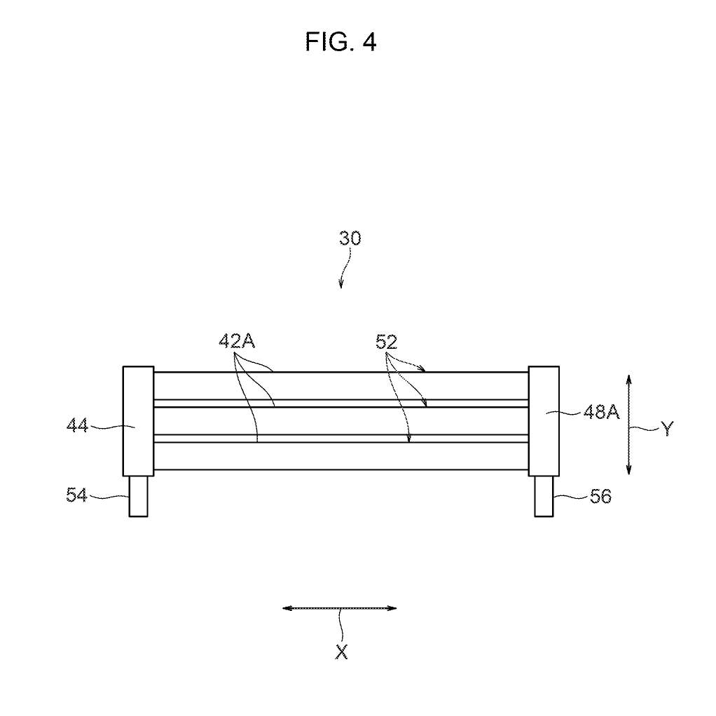

The plural pipes 42A to 42E are arrayed side-by-side in the vertical direction of the condenser 30 described above, and form a pipe group 52. As illustrated in FIG. 4, the condenser 30 is provided with plural such pipe groups 52. The plural pipe groups 52 are arrayed side-by-side in a y-direction that is a depth direction of the condenser 30. The depth direction of the condenser 30 is a direction orthogonal to both the side-by-side array direction of the plural pipes that form each pipe group 52 (the height direction of the condenser 30), and a length direction of the plural pipes (the lateral direction of the condenser 30).

As illustrated in FIG. 3, the inlet side coupling member 44 is provided by the side of the uppermost level pipe 42A. The tube shaped inlet 54, which protrudes out at a front face side of the condenser 30, is provided to the inlet side coupling member 44.

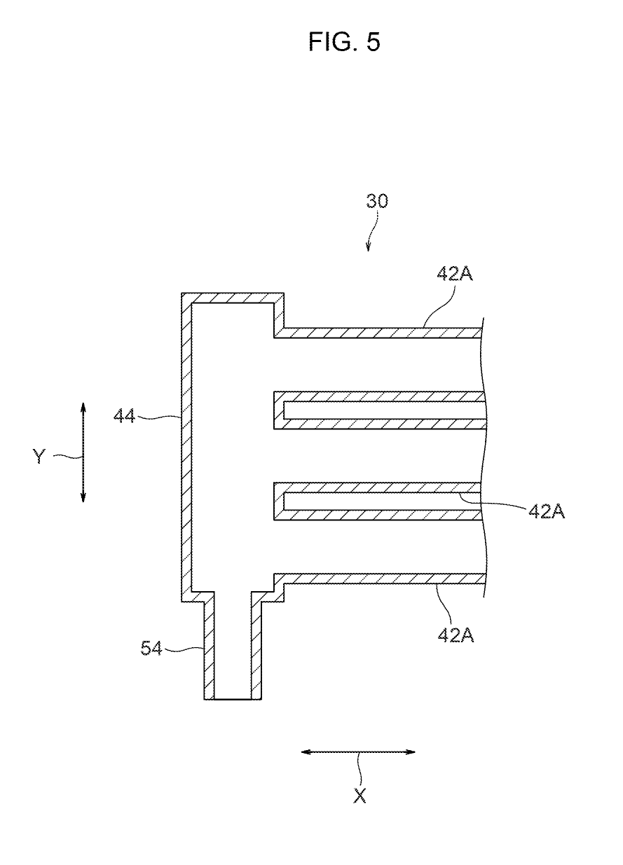

As illustrated in FIG. 4, the inlet side coupling member 44 extends in the depth direction of the condenser 30. One end of the uppermost level pipe 42A in each of the plural pipe groups 52 is connected to the inlet side coupling member 44. As illustrated in FIG. 5, the inlet side coupling member 44 is formed in a hollow shape, and the inlet 54 is coupled to each of the uppermost level pipes 42A through the inlet side coupling member 44.

As illustrated in FIG. 3, the outlet side coupling member 46 is provided beside the lowermost level pipe 42E. The outlet side coupling member 46 is disposed on the opposite side to the side on which the inlet side coupling member 44 is disposed. The tube shaped outlet 56, which protrudes out to the front face side of the condenser 30, is provided to the outlet side coupling member 46.

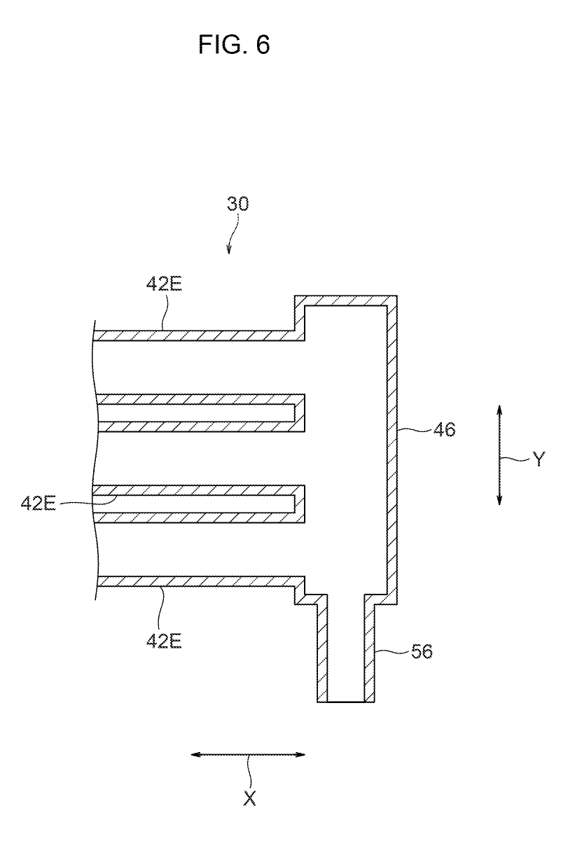

As illustrated in FIG. 6, the outlet side coupling member 46 extends in the depth direction of the condenser 30. One end of the lowermost level pipe 42E of each of the plural pipe groups 52 is connected to the outlet side coupling member 46. The outlet side coupling member 46 is formed in a hollow shape, and each of the lowermost level pipes 42E are in communication with the outlet 56 through the outlet side coupling member 46. As an example, the outlet side coupling member 46 is configured similarly to the inlet side coupling member 44.

As illustrated in FIG. 3, the plural tanks 48A to 48D couple together end portions of neighboring pipes among the plural pipes 42A to 42E. More specifically, the tank 48A couples an end portion at an outlet side of the pipe 42A to an end portion at an inlet side of the pipe 42B, and the tank 48B couples an end portion at an outlet side of the pipe 42B to an end portion at an inlet side of the pipe 42C. Moreover, the tank 48C couples an end portion at an outlet side of the pipe 42C to an end portion at an inlet side of the pipe 42D, and the tank 48D couples an end portion at an outlet side of the pipe 42D to an end portion at an inlet side of the pipe 42E. Moreover, the plural tanks 48A to 48D form a meandering coolant flow path together with the plural pipes 42A to 42E.

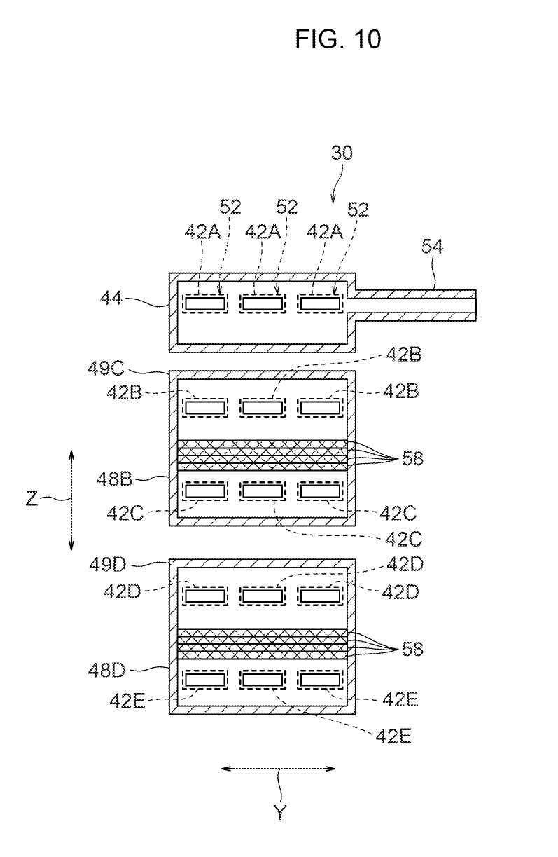

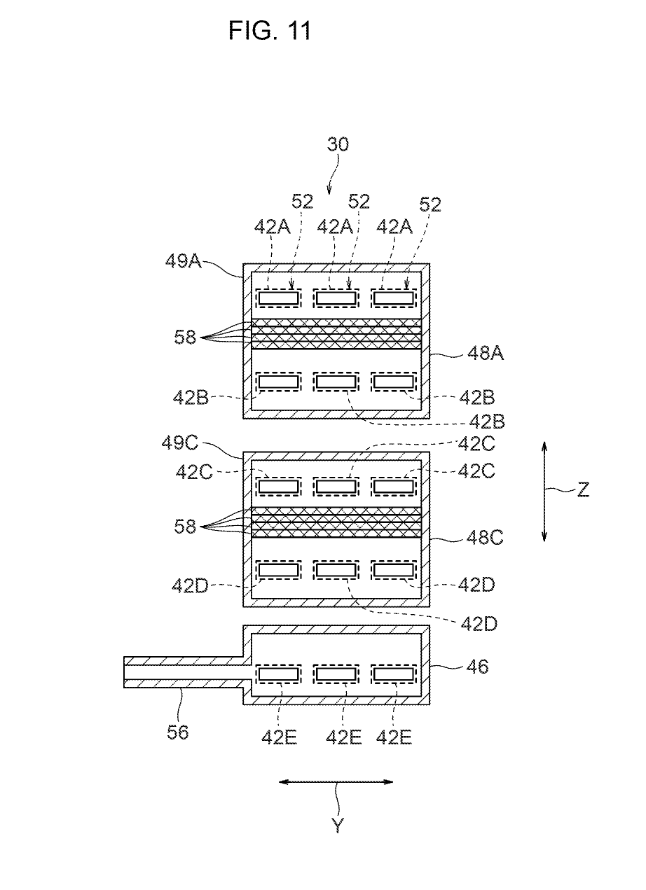

As illustrated in FIG. 10 and FIG. 11, similarly to the inlet side coupling member 44 and the outlet side coupling member 46 described above, the plural tanks 48A to 48D extend along the depth direction of the condenser 30 (the y-direction), which is the side-by-side array direction of the plural pipe groups 52. The plural tanks 48A to 48D are coupled to the plural pipe groups 52.

Namely, as illustrated in FIG. 11, end portions at the outlet side of the uppermost level pipe 42A of each of the pipe groups 52 are coupled together by an upper portion of the tank 48A, the end portions at the inlet side of the second level pipe 42B of each of the pipe groups 52 are coupled together by a lower portion of the tank 48A. The end portions of the outlet side of each of the uppermost level pipes 42A are thereby placed in communication with the end portions at the inlet side of each of the second level pipes 42B by the tank 48A.

Similarly, as illustrated in FIG. 10, the end portions at the outlet side of the second level pipes 42B in each of the pipe groups 52 are coupled together by an upper portion of the tank 48B, and the end portions at the inlet side of the third level pipes 42C of each of the pipe groups 52 are coupled together by a lower portion of the tank 48B. The end portions at the outlet side of each of the second level pipes 42B are thereby placed in communication with the end portions at the inlet side of each of the third level pipes 42C by the tank 48B.

Moreover, as illustrated in FIG. 11, the end portions at the outlet side of the third level pipes 42C in each of the pipe groups 52 are coupled together by an upper portion of the tank 48C, and the end portions of the inlet side at the fourth level pipes 42D of each of the pipe groups 52 are coupled together by a lower portion of the tank 48C. The end portions at the outlet side of each of the third level pipes 42C are thereby placed in communication with the end portions at the inlet side of each of the fourth level pipes 42D by the tank 48C.

Moreover, as illustrated in FIG. 10, the end portions at the outlet side of the fourth level pipes 42D in each of the pipe groups 52 are coupled together by an upper portion of the tank 48D, and the end portions at the inlet side of the lowermost level pipes 42E of each of the pipe groups 52 are coupled together by a lower portion of the tank 48D. The end portions at the outlet side of each of the fourth level pipes 42D are thereby placed in communication with the end portions at the inlet side of each of the lowermost level pipes 42E by the tank 48D.

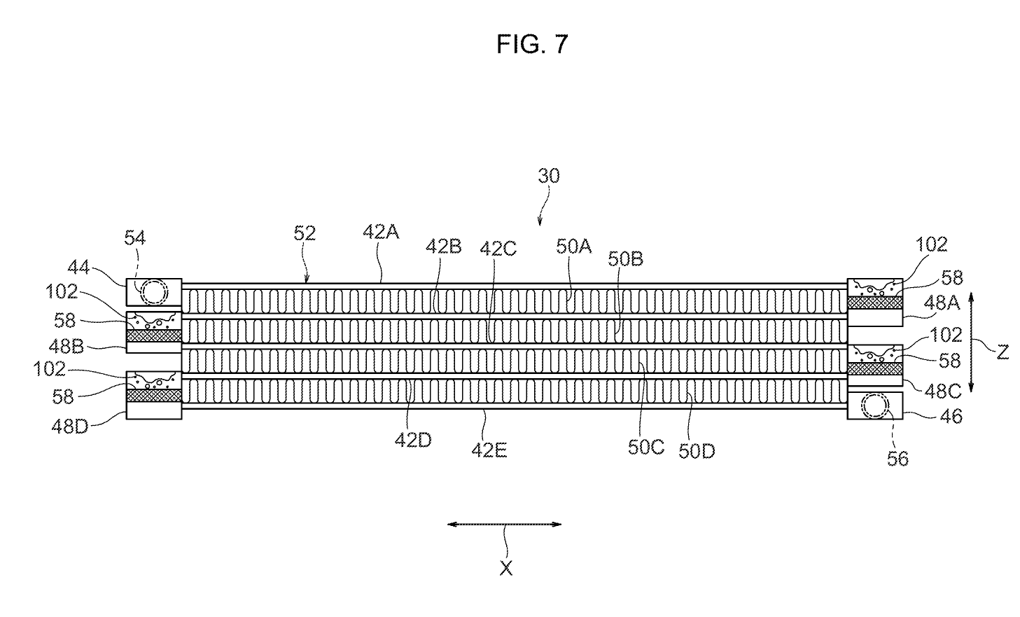

As illustrated in FIG. 7, the plural tanks 48A to 48D allow coolant to flow from one pipe of neighboring pipes to another of the neighboring pipes among the plural pipes 42A to 42E. The coolant flowing into the inlet side coupling member 44 through the inlet 54 is delivered to the outlet side coupling member 46 through the plural pipes 42A to 42E and the plural tanks 48A to 48D, and the coolant delivered to the outlet side coupling member 46 is then delivered to outside through the outlet 56. The coolant is condensed in the condenser 30 due to exchanging heat with the cooling airflow while passing through the plural pipes 42A to 42E.

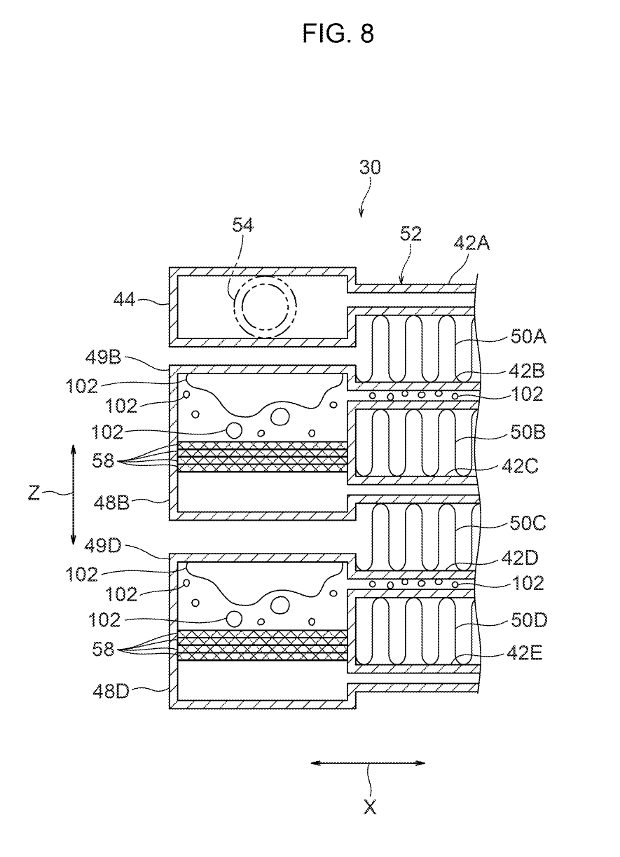

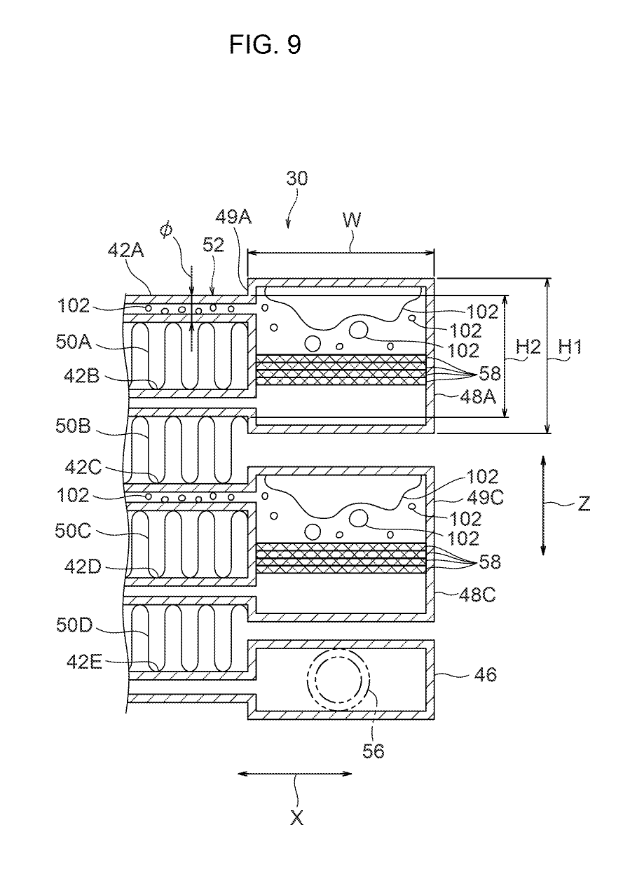

Bubbles 102 are sometimes generated inside the plural pipes 42A to 42E described above due temperature increase, agitation, and the like in the coolant (see FIG. 8 and FIG. 9 for more details). The bubbles 102 refer not only to small, isolated bubbles, but also to large residual spaces in the coolant. There is a concern that bubbles 102 remaining inside the pipes 42A to 42E could decrease the flow velocity of the coolant, and decrease the heat transfer by the coolant, thus decreasing the cooling efficiency.

The plural tanks 48A to 48D described above therefore have a shape and volume so as to enable bubbles 102 contained in the coolant to be collected. More specifically, as an example, each of the tanks 48A to 48D is formed with a quadrilateral cross-section profile. As illustrated in FIG. 9, the height H1 of each tank is set greater than the width H2 between the upper pipe end and the lower pipe end of neighboring pipes. Moreover, the width W along the horizontal direction of each tank is set greater than the outer diameter φ of each of the pipes.

Respective upper portions 49A to 49D of the plural tanks 48A to 48D protrude further upward than the pipe on the upper side out of neighboring pipes. Namely, as illustrated in FIG. 9, the upper portion 49A of the tank 48A protrudes further upward than the pipe 42A, and the upper portion 49C of the tank 48C protrudes further upward than the pipe 42C. Moreover, as illustrated in FIG. 8, the upper portion 49B of the tank 48B protrudes further upward than the pipe 42B, and the upper portion 49D of the tank 48D protrudes further upward than the pipe 42D.

As an example, the plural tanks 48A to 48D are configured with matching cross-section profiles. Moreover, the plural tanks 48A to 48D have sufficient volume that the interiors thereof are not filled by the coolant when the coolant flows through the pipe 42A to the pipe 42E.

Moreover, plural flow regulating members 58 are respectively provided inside each of the tanks 48A to 48D. The flow regulating members 58 have functions of shrinking bubbles 102 contained in the coolant, and separating bubbles 102 contained in the coolant from the coolant. Each of the flow regulating members 58 is formed with a flat plate shape, and is provided running along the horizontal direction of the condenser 30. The plural flow regulating members 58 are disposed in a row in the vertical direction of the condenser 30 inside the respective tanks 48A to 48D, and segment the interiors of the respective tanks 48A to 48D in the vertical direction. The plural flow regulating members 58 are disposed below a vertical direction central portion of the tanks 48A to 48D inside the respective tanks 48A to 48D.

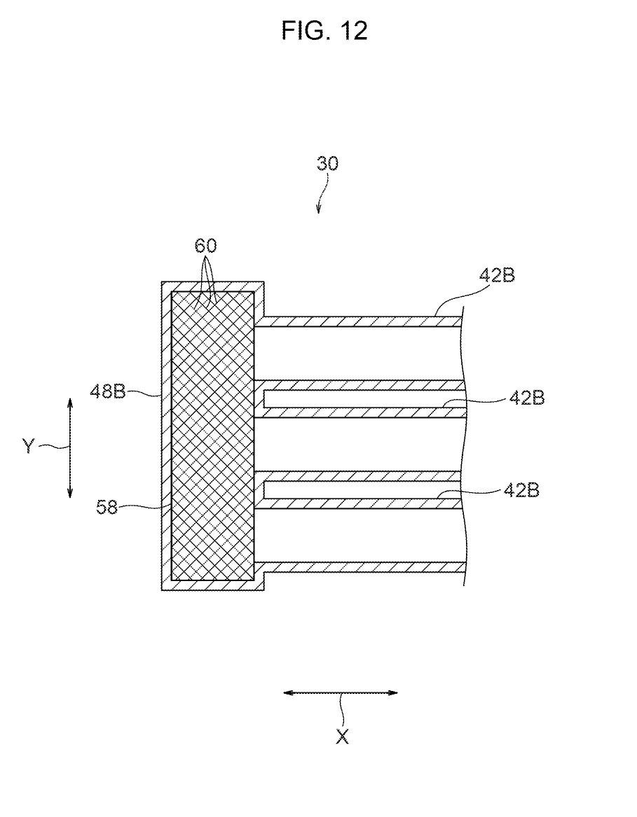

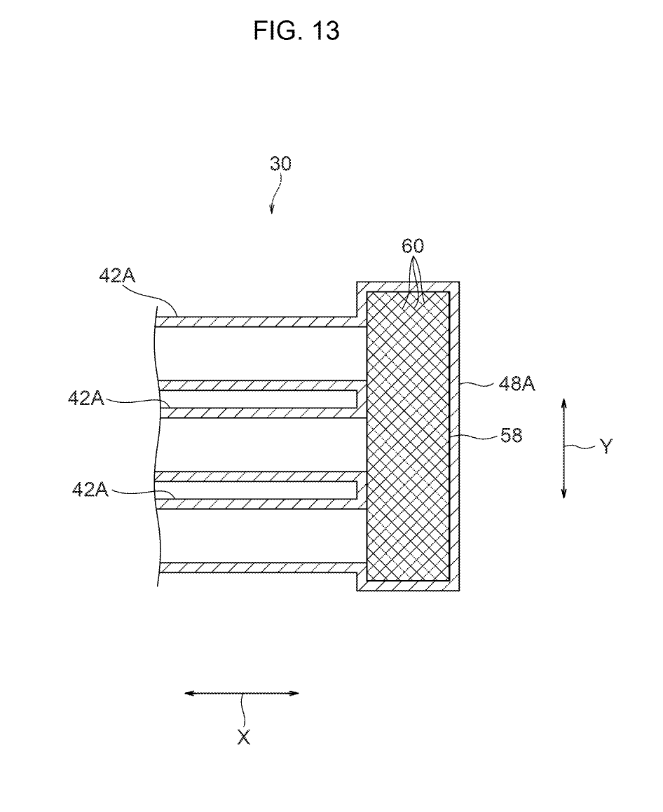

The coolant flowing from one of the neighboring pipes to another of neighboring pipes out of the plural pipes 42A to 42E passes through the plural flow regulating members 58, inside the respective tanks 48A to 48D. As illustrated in FIG. 12 and FIG. 13, as an example, each of the flow regulating members 58 is formed in a mesh form. Moreover, a multiplicity of openings 60, which the coolant passes through, is formed in each of the flow regulating members 58.

The widths (minimum widths) of the multiplicity of openings 60 are all set to 100 μm or greater. Inside the respective tanks 48A to 48D, the plural flow regulating members 58 shrink bubbles contained in the coolant that passes through the plural flow regulating members 58, or separate bubbles contained in the coolant that passes through the plural flow regulating members 58 from the coolant. Shrinking and separation of the bubbles is enabled by setting the widths (minimum widths) of the multiplicity of openings 60 to 100 μm or greater. The coolant that passes through the plural flow regulating members 58 is converted from a turbulent flow including bubbles to a laminar flow inside of each of the tanks 48A to 48D.

The flow regulating members 58 are preferably formed from metal, and fixed to the tanks 48A to 48D. When the flow regulating members 58 and the tanks 48A to 48D are all made from metal, the flow regulating members 58 and the tanks 48A to 48D are preferably formed from a combination of materials that will not electrochemically react with each other.

Explanation next follows regarding operation and advantageous effects of the present exemplary embodiment.

As explained in detail above, in the present exemplary embodiment, end portions of neighboring pipes among the plural pipes 42A to 42E are coupled together by the respective tanks 48A to 48D. Accordingly, as illustrated in FIG. 8 and FIG. 9, when the coolant flows through the tanks 48A to 48D from one of neighboring pipes to another of neighboring pipes, the bubbles 102 contained in the coolant can be collected in the tanks 48A to 48D, even in cases in which bubbles 102 are generated in the coolant inside the respective pipes 42A to 42E. Bubbles 102 contained in the coolant flowing through the inside of the plural pipes 42A to 42E can accordingly be reduced, enabling the flow velocity of the coolant to be secured. The heat transfer by the coolant is thereby promoted, enabling the cooling efficiency of the condenser 30 to be improved.

The plural tanks 48A to 48D form the meandering coolant flow path together with the plural pipes 42A to 42E. Separation and diffusion of bubbles 102 contained in the coolant is performed in each of the tanks 48A to 48D, and the coolant is supplied to the pipes from the respective tanks 48A to 48D in a state in which the bubbles 102 are diminished (a state in which the coolant is refreshed). This enables the flow velocity of the coolant to be secured, and enables heat transfer by the coolant to be further promoted.

Moreover, as illustrated in FIG. 9, the height H1 of each of the tanks is set greater than the width H2 between the uppermost end and the lowermost end of the neighboring pipes. The width W along the horizontal direction of each of the tanks is set larger than the outer diameter φ of the respective pipes. The capacities of the tanks 48A to 48D are thereby secured, enabling bubbles 102 to be effectively collected in the tanks 48A to 48D.

In particular, the respective upper portions 49A to 49D of the plural tanks 48A to 48D protrude further upward than the respective pipes at the upper side out of neighboring pipes. A greater amount of bubbles 102 can accordingly be collected in the tanks 48A to 48D.

Moreover, plural of the flow regulating members 58 are provided inside each of the tanks 48A to 48D. Each of the flow regulating members 58 has the functions of shrinking bubbles 102 contained in the coolant, and separating bubbles 102 contained in the coolant from the coolant. Namely, large bubbles 102 are shrunk by the flow regulating members 58, and small bubbles 102 are separated from the coolant by the flow regulating members 58. The bubbles 102 contained in the coolant can accordingly be further reduced by each of the flow regulating members 58, enabling the flow velocity of the coolant to be even better secured.

Moreover, as described above, since the bubbles 102 contained in the coolant can be further reduced by each of the flow regulating members 58, a decrease in the heat transfer coefficient of the coolant caused by mixing in of bubbles can be suppressed. Accordingly, this enables the cooling efficiency of the condenser 30 to be further improved.

Moreover, the plural flow regulating members 58 inside of each of the tanks 48A to 48D segment the interior of the tanks 48A to 48D in the vertical direction. A space for storing bubbles 102 is thereby secured above the plural flow regulating members 58 inside each of the tanks 48A to 48D. Bubbles 102 separated from the coolant by the plural flow regulating members 58 can therefore be collected in the upper portions of the tanks 48A to 48D.

The plural flow regulating members 58 are provided along the horizontal direction of the condenser 30 in each of the tanks 48A to 48D. The cross-section surface area of the flow regulating members 58 along a direction orthogonal to the flow direction of the coolant in the tanks can accordingly be secured, enabling shrinking of bubbles 102 contained in the coolant, and separation of bubbles 102 included in the coolant from the coolant, to be performed more effectively.

Moreover, inside each of the tanks 48A to 48D, the plural flow regulating members 58 are disposed below the vertical direction central portion of the tanks 48A to 48D. Greater space for collecting bubbles 102 can thereby be secured in the space above the plural flow regulating members 58 inside each of the tanks 48A to 48D.

Moreover, inside each of the tanks 48A to 48D, the plural flow regulating members 58 are disposed in a row along the vertical direction. Since the coolant accordingly passes through a greater number of the flow regulating members 58, this enables shrinking of bubbles 102 contained in the coolant, and separation of bubbles 102 included in the coolant from the coolant to be performed more effectively.

Moreover, as illustrated in FIG. 7, the pipe 42A of the uppermost level (furthest to the upstream side) is exposed at the opposite side from the side of the heat dissipation fin 50A interposed between the pipe 42A and the second level pipe 42B, and forms the upper end of the condenser 30. Since the coolant flowing through the pipe 42A, which is furthest to the upstream side, is scavenged with the temperature state thereof maintained as is, bubbles 102 in the coolant can be shrunk or separated efficiently in the tank 48A.

The plural tanks 48A to 48D form the meandering coolant flow path together with the plural pipes 42A to 42E. The coolant flow path can accordingly be made longer, enabling the cooling efficiency of the condenser 30 to be further improved.

Moreover, inside each of the tanks 48A to 48D, the plural flow regulating members 58 convert the coolant that passes through the plural flow regulating members 58 from a turbulent flow including bubbles 102 to a laminar flow. This enables the resistance inside the plural pipes 42A to 42E to be reduced, enabling a decrease in pressure loss of the coolant flowing in the plural pipes 42A to 42E.

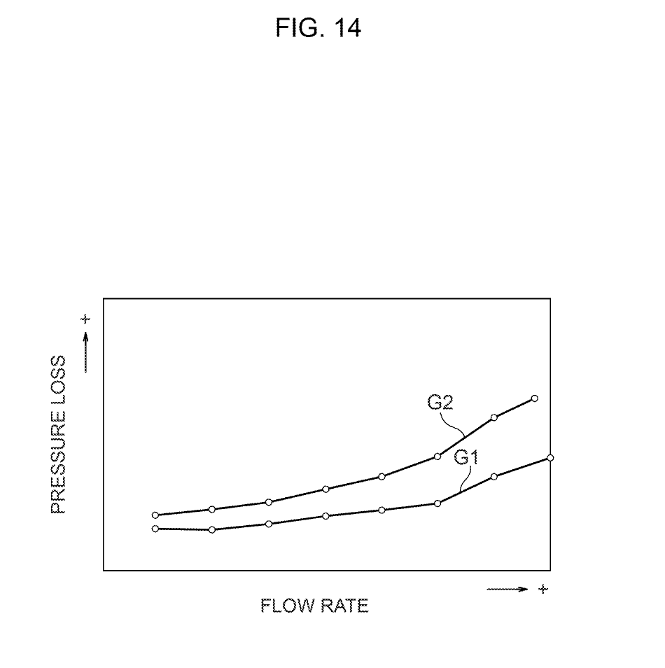

Results of measuring a relationship between the flow rate of the coolant flowing in the plural pipes, and the pressure loss of the coolant flowing in the plural pipes is illustrated in FIG. 14. Graph G1 is a measurement result for a cooling system according to the present exemplary embodiment, and Graph G2 is a measurement result for a cooling system according to a comparative example.

In the cooling system according to the comparative example, a cooling circuit in which a single pipe member is bent so as to meander is provided in place of a cooling circuit of the present exemplary embodiment. As illustrated in FIG. 14, in the present exemplary embodiment, the pressure loss of the coolant flowing through the plural pipes can be decreased compared to the comparative example.

Explanation next follows regarding modified examples of the present exemplary embodiment.

The height H1 of each of the tanks in the above exemplary embodiment is set greater than the width H2 between the uppermost end and the lowermost end of the neighboring pipes. However, the height H1 of each of the tanks may be equivalent to the width H2 between the uppermost end and the lowermost end of the neighboring pipes. Moreover, in such cases, the upper ends of the tanks 48A to 48D may be positioned at the same height as the upper end of the pipe on the upper side out of the neighboring pipes.

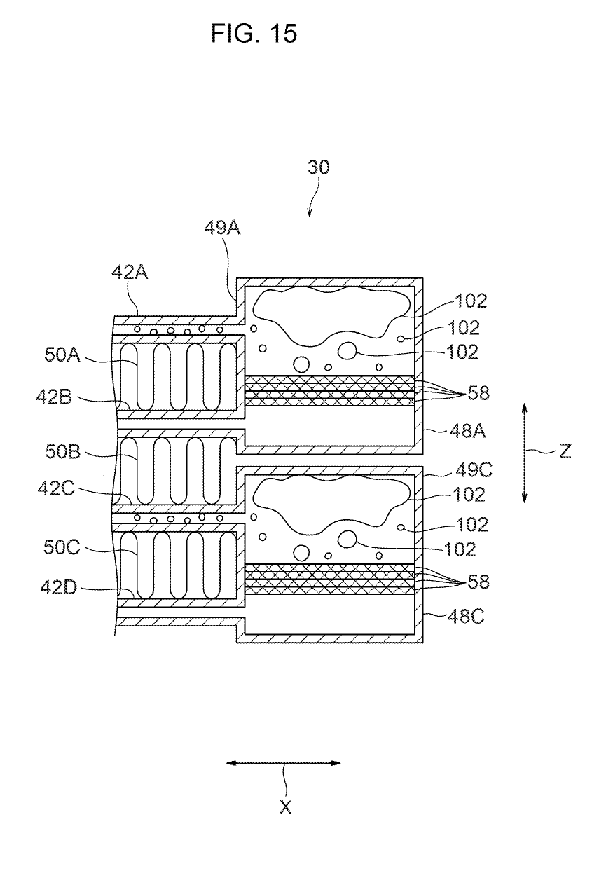

Moreover, as illustrated in FIG. 15, the upper portion of the tank 48C may be extended upwards, and may face the lower portion of the tank 48A that is adjacent to the tank 48C from close proximity. Moreover, tanks other than the tank 48C may be formed similarly to the tank 48C.

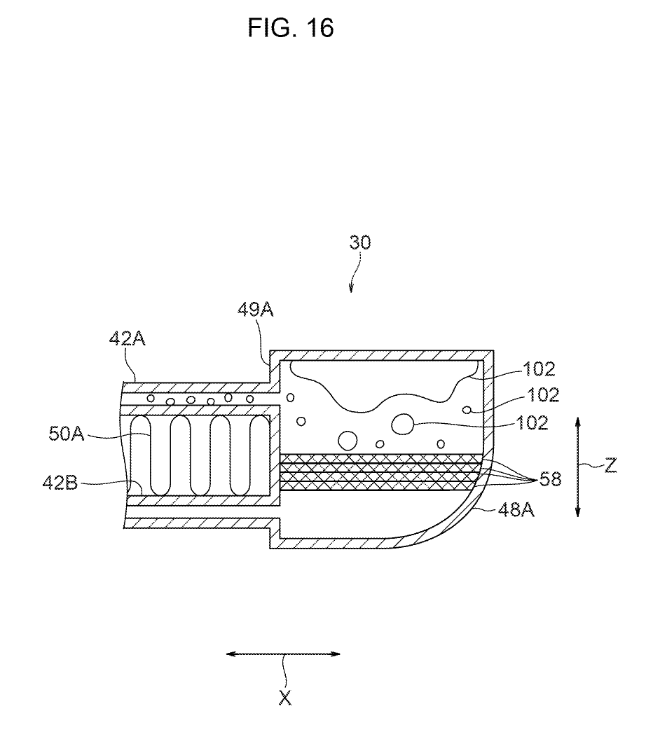

Each of the tanks 48A to 48D is formed with a quadrilateral cross-section profile. However, each of the tanks 48A to 48D may be formed, for example, such that a corner of a lower outer side of each tank forms an arc shape like in the tank 48A illustrated in FIG. 16. Such a configuration enables the coolant flow smoothly from the tanks to the pipes.

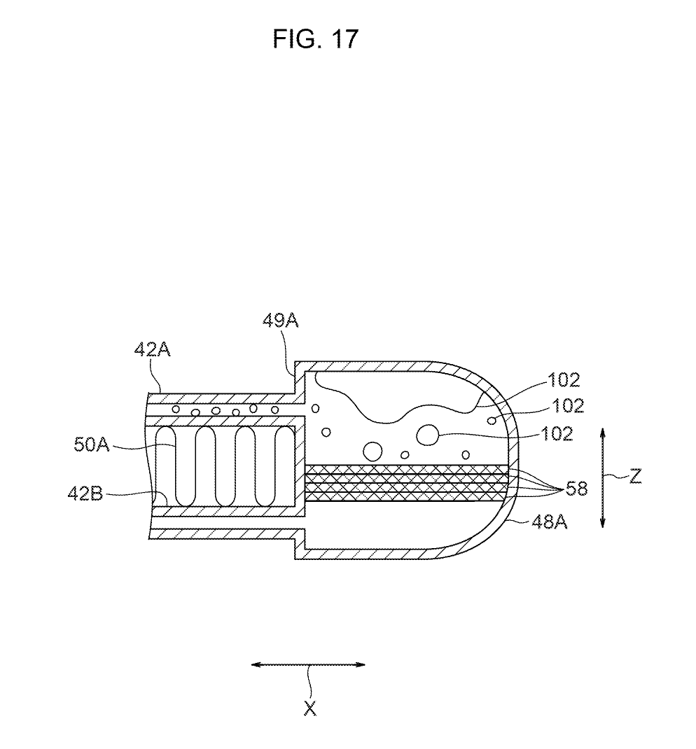

Moreover, in each of the tanks 48A to 48D, for example, a corner of an upper outer side may be formed with an arc shape in addition to the corner of the lower outer side of the tank, like in the tank 48A illustrated in FIG. 17. Such a configuration enables coolant to flow smoothly from one pipe to another pipe through the tanks

Moreover, although the plural tanks 48A to 48D are formed independently from one another, the plural tanks 48A to 48D may be integrally formed.

In the above exemplary embodiment, the respective flow regulating members 58 have the functions of both shrinking the bubbles 102 included in the coolant and separating the bubbles 102 included in the coolant from the coolant. However, the respective flow regulating members 58 may have just one function out of shrinking the bubbles 102 contained in the coolant or separating the bubbles 102 included in the coolant from the coolant.

Moreover, plural flow regulating members 58 are provided inside each of the tanks 48A to 48D. However, a single flow regulating member 58 may be provided inside each of the tanks 48A to 48D.

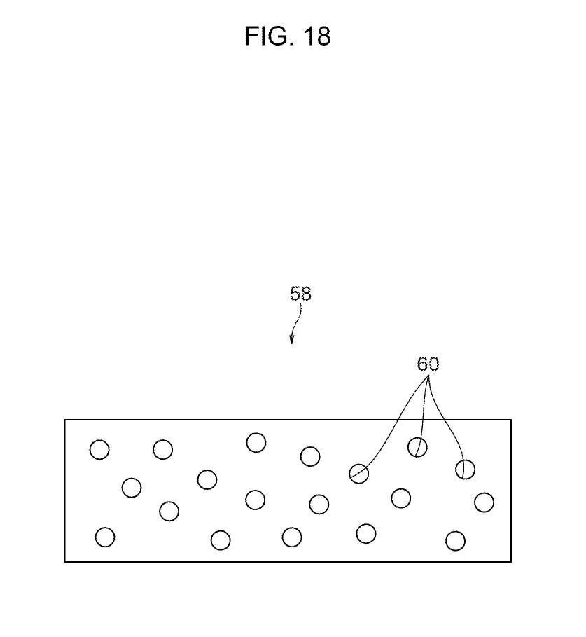

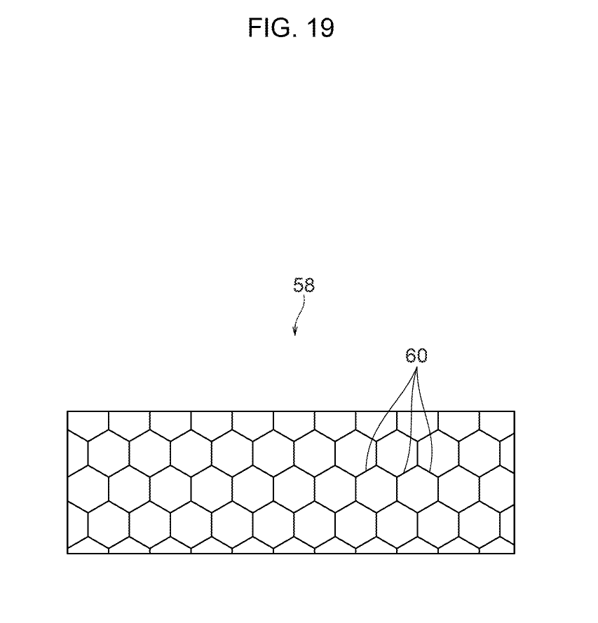

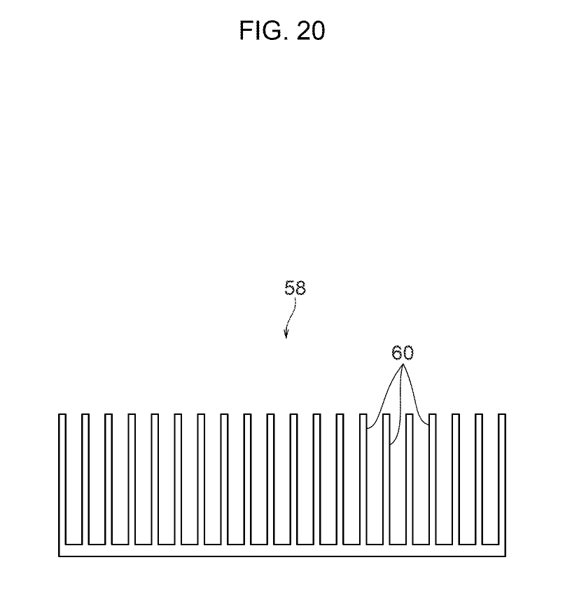

Moreover, the flow regulating members 58 are formed in a mesh form. However, the flow regulating members 58 may be formed with a porous form as illustrated in FIG. 18, or may be formed with a honeycomb form as illustrated in FIG. 19. Moreover, the flow regulating members 58 may be formed with a comb form as illustrated in FIG. 20.

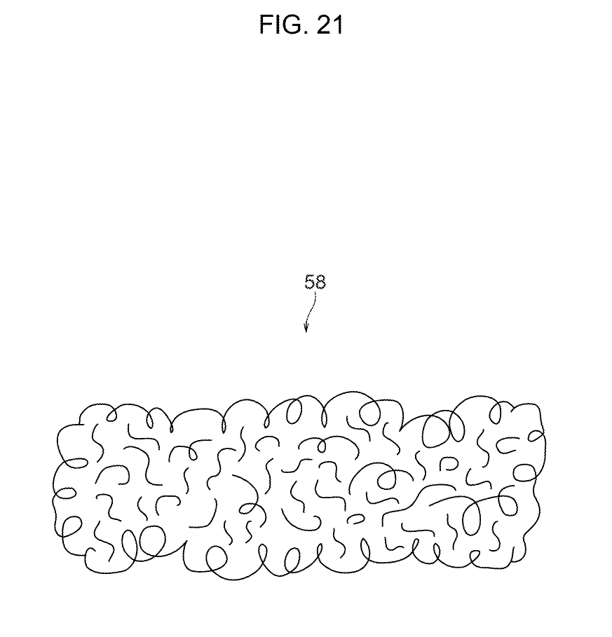

In cases in which the flow regulating members 58 have either a porous form, a honeycomb form, or a comb form, the multiplicity of openings 60 that the coolant passes through are formed in the flow regulating members 58. The width (minimum width) of each of the multiplicity of openings 60 is set to 100 μm or greater. Note that the flow regulating members 58 may be formed with a steel wool form as illustrated in FIG. 21.

Moreover, the respective flow regulating members 58 may have any form as long as it is a form capable of performing at least one of shrinking bubbles 102 included in the coolant or separating bubbles 102 included in the coolant from the coolant.

Moreover, although the respective flow regulating members 58 are preferably fixed around the entire periphery inside of each of the plural tanks 48A to 48D, each of the flow regulating members 58 may be fixed in a cantilever form inside the plural tanks 48A to 48D. Moreover, the flow regulating members 58 may vibrate accompanying the passage of the coolant, thereby promoting shrinking and separation of bubbles 102.

Moreover, the plural flow regulating members 58 in each of the tanks 48A to 48D may be separated from one another, or may overlap with one another, in an upright direction of the condenser 30. The openings 60 of the plural flow regulating members 58 in each of the tanks 48 may be disposed at mutually different positions.

Moreover, hydrophilicity may be imparted to the insides of the plural pipes 42A to 42E and to the insides the plural tanks 48A to 48D by blast treatment or by coating treatment.

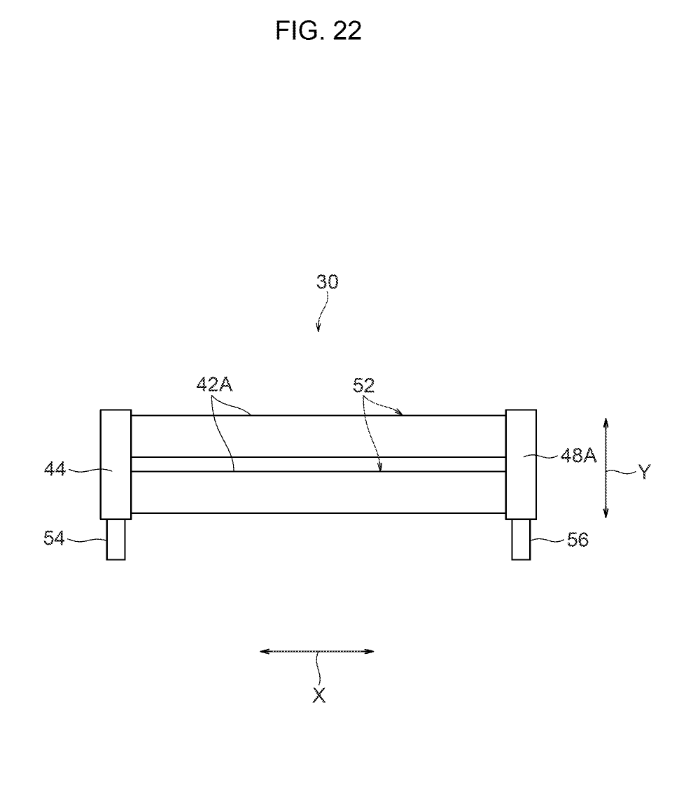

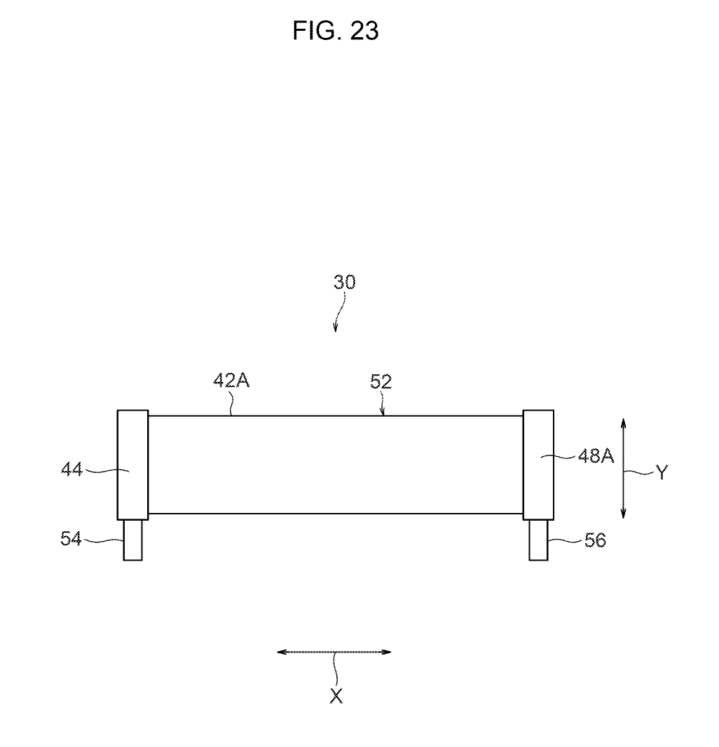

Moreover, in the above exemplary embodiment, the condenser 30 includes plural pipe groups 52. However, the condenser 30 may contain a pair of the pipe groups 52 as illustrated in FIG. 22, or may contain a single pipe group 52 alone as illustrated in FIG. 23.

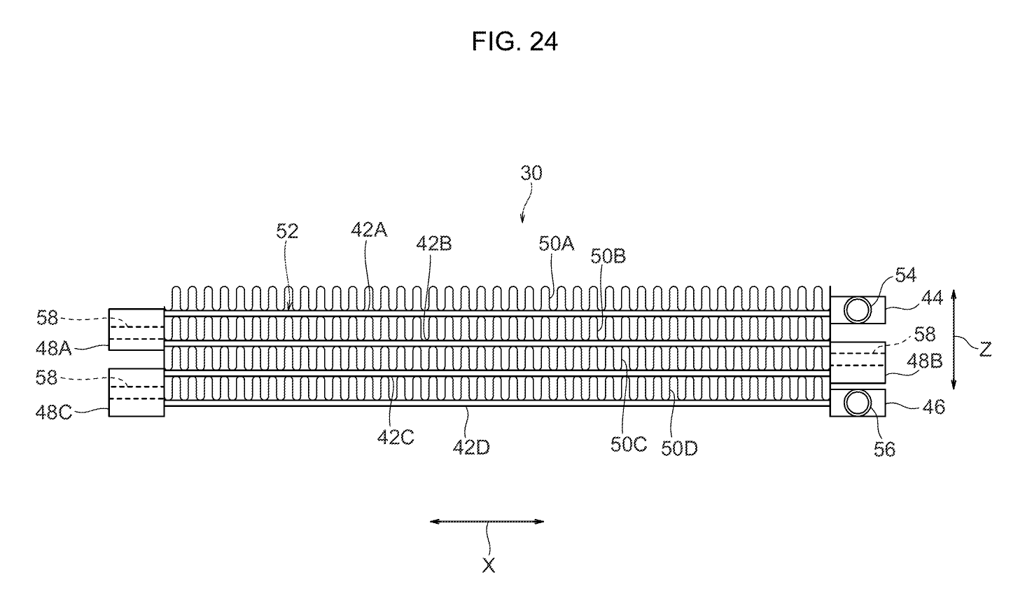

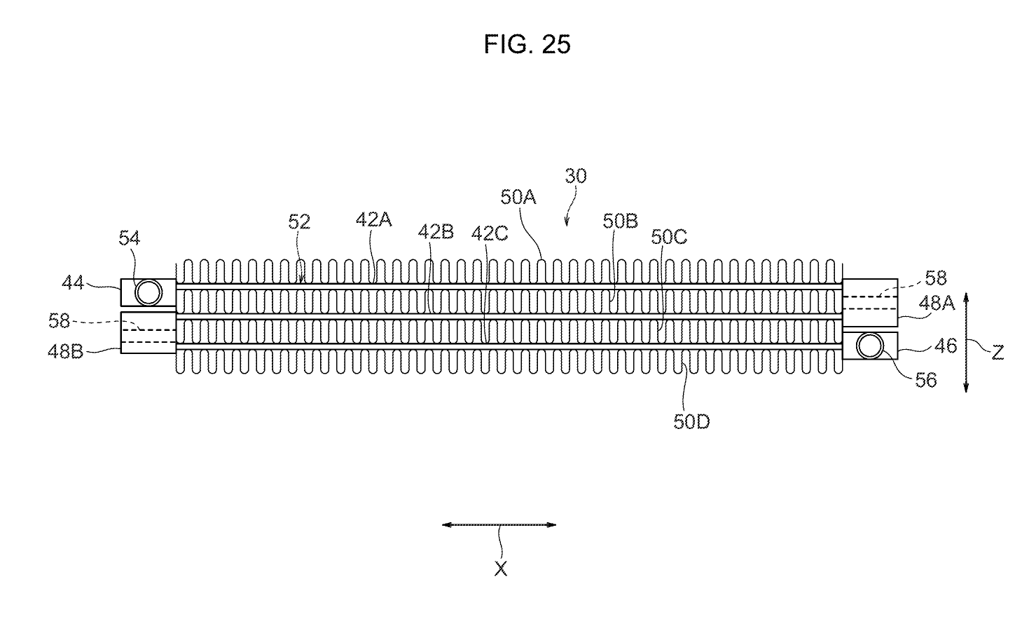

The coolant flow path of the condenser 30 is formed by three or more pipes and plural tanks However, the coolant flow path of the condenser 30 may be formed by two pipes side-by-side, and a single tank coupling the end portions of the two neighboring pipes together. Namely, the coolant flow path of the condenser 30 may be formed in a C shape rather than a meandering shape in the front face view of the condenser 30. Moreover, the coolant flow path of the condenser 30 may, for example, include pipes 42A to 42D on four levels as illustrated in FIG. 24, or may include pipes 42A to 42C on three levels as illustrated in FIG. 25.

Moreover, the plural pipes on respective levels in a row along the depth direction may form a meandering coolant flow path in the condenser 30. When configuration is made in this manner, the coolant flow path can be made long, enabling the cooling efficiency of the condenser 30 to be further improved.

Moreover, the condenser 30 is provided with plural tanks 48A to 48D that couple together end portions of neighboring pipes among the plural pipes 42A to 42E. However, end portions of the neighboring pipes among the plural pipes 42A to 42E may be coupled together by plural coupling portions other than the plural tanks 48A to 48D.

The cooling airflow 100 that is an example of an external fluid is supplied to the condenser 30. However, an external fluid other than the cooling airflow may be supplied to the condenser 30.

In the above exemplary embodiment, the cooling system 20 is provided with the circulation pump 36. However, instead of providing the circulation pump 36, the cooling system 20 may be configured such that the coolant is circulated between the condenser 30 and the evaporator 28 by disposing the condenser 30 at a position higher than the upright direction height of the evaporator 28.

Moreover, the cooling system 20 includes the evaporator 28 that vaporizes the coolant using heat generated by the heat generating body 24, and the condenser 30 that condenses the vaporized coolant using heat exchange with the external fluid, and is thus configured to utilize latent heat.

However, instead of the evaporator 28, the cooling system 20 may include a heat receiver in which the coolant absorbs heat generated by the heat generating 24 body, and instead of the condenser 30, may include a heat dissipater that dissipates heat from the coolant using heat exchange with the external fluid. Namely, the cooling system 20 may be configured to utilize sensible heat.

Note that out of the plural modified examples above, modified examples that can be combined may be combined as appropriate.

Technology disclosed herein enables cooling efficiency to be improved.

Although an exemplary embodiment of technology disclosed herein has been explained above, technology disclosed herein is not limited to the above. It is obvious that various modifications may be implemented in addition to the above within a scope not exceeding the spirit of the invention.

All cited documents, patent applications and technical standards mentioned in the present specification are incorporated by reference in the present specification to the same extent as if the individual cited documents, patent applications and technical standards were specifically and individually incorporated by reference in the present specification.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A heat exchanger comprising:
a plurality of pipes arrayed side-by-side; and
a tank that couples together end portions of neighboring pipes among the plurality of pipes, and that allows coolant to flow from one of the neighboring pipes to another of the neighboring pipes.

2. The heat exchanger of claim 1, wherein the tank collects bubbles contained in the coolant.

3. The heat exchanger of claim 1, wherein:
the plurality of pipes are arrayed side-by-side in a vertical direction; and
a height of the tank is equal to or greater than a width between an upper pipe end and a lower pipe end of neighboring pipes.

4. The heat exchanger of claim 3, wherein a width of the tank along a horizontal direction is greater than a pipe outer diameter.

5. The heat exchanger of claim 3, wherein an upper portion of the tank protrudes further upward than a pipe on an upper side out of the neighboring pipes.

6. The heat exchanger of claim 1, comprising a plurality of the tank, wherein the plurality of tanks form a meandering coolant flow path together with the plurality of pipes.

7. The heat exchanger of claim 1, wherein:
a flow regulating member, through which the coolant flowing from one neighboring pipe to another neighboring pipe passes, is provided inside the tank; and
the flow regulating member performs at least one of shrinking bubbles included in the coolant or separating bubbles included in the coolant from the coolant.

8. A heat exchanger comprising:
a plurality of pipes arrayed side-by-side;
a coupling portion that couples together end portions of neighboring pipes among the plurality of pipes, and that allows coolant to flow from one of the neighboring pipes to another of the neighboring pipes; and
a flow regulating member that is provided inside the coupling portion, through which the coolant flowing from one neighboring pipe to another neighboring pipes passes, and that performs at least one of shrinking bubbles included in the coolant or separating bubbles included in the coolant from the coolant.

9. The heat exchanger of claim 8, wherein the flow regulating member converts the coolant passing through the flow regulating member into a laminar flow.

10. The heat exchanger of claim 8, wherein:
the plurality of pipes are arrayed side-by-side in a vertical direction; and
the flow regulating member segments an inside of the tank in the vertical direction.

11. The heat exchanger of claim 10, wherein the flow regulating member is provided along a horizontal direction.

12. The heat exchanger of claim 10, wherein the flow regulating member is disposed below a vertical direction central portion of the tank.

13. The heat exchanger of claim 10, comprising a plurality of the flow regulating member, wherein the plurality of flow regulating members are disposed in a row along the vertical direction.

14. The heat exchanger of claim 8, wherein:
a multiplicity of openings through which the coolant passes is formed in the flow regulating member; and
the width of each of the multiplicity of openings is set to 100 μm or greater.

15. The heat exchanger of claim 8, wherein a form of the flow regulating member is either a mesh form, a porous form, a honeycomb form, a comb form, or a steel wool form.

16. The heat exchanger of claim 1, wherein a heat dissipation fin is interposed between the neighboring pipes.

17. The heat exchanger of claim 16, wherein an uppermost level pipe among the plurality of pipes is exposed at an opposite side from a side of the heat dissipation fin.

18. The heat exchanger of claim 1, comprising a plurality of pipe groups that each includes a plurality of pipes, wherein:
the plurality of pipe groups are arrayed side-by-side in a direction orthogonal to both a side-by-side array direction of the plurality of pipes, and a length direction of the plurality of pipes; and
the tank extends in a side-by-side array direction of the plurality of pipe groups, and couples the plurality of pipes groups together.

19. A cooling system comprising:
a heat receiver that absorbs heat generated by a heat generating body into a coolant; and
a heat dissipater serving as the heat exchanger of claim 1, wherein the coolant is circulated between the heat dissipater and the heat receiver, and the heat dissipater dissipates heat from the coolant by exchanging heat with an external fluid.

20. An electronic device comprising:
a heat generating body; and
the cooling system of claim 19.
